(19) United States
(12) Patent Application Publication
(10) Pub. No.: US 2017/0133521 A1
(43) Pub. Date: May 11, 2017

(54) A METHOD FOR FORMING A PHOTOVOLTAIC CELL AND A PHOTOVOLTAIC CELL FORMED ACCORDING TO THE METHOD

(71) Applicant: Vincent Akira Allen, Balgownie, NSW (AU)

(72) Inventor: Vincent Akira Allen, Balgownie, NSW (AU)

(21) Appl. No.: 15/323,536

(22) PCT Filed: Jul. 2, 2015
(86) PCT No.: PCT/AU2015/000389

§ 371 Date: Jan. 3, 2017

(30) Foreign Application Priority Data
Jul. 2, 2014 (AU) 2014902547

(51) Int. Cl. H01L 31/02; H01L 31/18; H01L 31/0747; H01L 31/0224

(52) U.S. Cl. CPC H01L 31/02008; H01L 31/022466; H01L 31/1884; H01L 31/022425; H01L 31/0747

(57) ABSTRACT

The present disclosure provides a method for forming a contact for a photovoltaic device and a photovoltaic device manufactured according to the method. The method comprises the steps of: depositing a polymeric layer onto a surface of the photovoltaic device; exposing a region of the polymeric layer to laser light; developing the polymeric layer to create at least one opening in the polymeric layer for accessing a respective portion of the surface; depositing a conductive material into the at least one opening of the polymeric layer in a manner such that the conductive material is in electrical contact with the respective portion of the surface; and removing at least a portion of the remaining developed polymeric layer from the surface.

### FIELD OF THE INVENTION

The present invention relates to a method for forming a photovoltaic cell and a photovoltaic cell formed according to the method.

### BACKGROUND OF THE INVENTION

Solar cells absorb the energy of incoming photons from the sun to generate electrical power. The absorbed photons provide energy to generate electron-hole pairs in the solar cell, which are driven by an electric field towards respective electrical contacts. Front and back electrical contacts allow collecting the electrons and holes and thus extracting current from the solar cells.

Commercially available solar cells generally have a patterned front contact. Often the front contact is configured as a plurality of conductive fingers that run across the front surface of the solar cell, and peripheral busbars that collect carriers from the fingers and are connected to an external circuit. The front contact pattern is generally designed to occupy only a small area of the front surface of the cell to minimise shading losses.

The front contact pattern is generally realised using a ‘screen-printing step’. Depending on the application, the cell back contact may also be realised by screen-printing and may also be patterned.

Screen-printing consists in forcing a metal paste through holes of a screen print mask, which has a prefabricated pattern. The metal paste is generally a silver based paste. The silver based paste provides good screen-printing performance, in particular for the front contact of many commercial solar cells. However, the constant drop of silicon prices and the high cost of silver have made the screen printing step a major contributor to the final cost of current solar cell devices.

Less expensive materials, such as copper, may be used to realise the electrical contacts of a solar cell. However, copper has proven to not be suitable for screen-printing and manufacturers of solar cells have been investigating new methods to apply copper contacts to their devices.

Alternative methods to realise electrical contacts for a solar cell are available and their performance has been proven in a laboratory environment. These methods, however, generally require processing steps which are not compatible with the low cost and high throughput requirements typical in a high volume solar cell production environment. The majority of these methods require an alignment step and a masking step to perform photolithography and create openings to form the contacts. These steps allow creating a precise high-resolution pattern on a surface of a device. The pattern may be created in a sacrificial layer and openings of the pattern may be used to deposit a metallic material, such as copper. Photoresist material with different properties is used depending on the resolution required to realise the pattern. Generally, high resolution photoresists are more expensive than photoresists with a lower resolution.

Traditional photolithography is not a viable process for high volume manufacturing of solar cells because it requires precise alignment of a mask and spinning of a photosensitive material (photoresist). The alignment step can be complex and time consuming. It would be desirable to have a patterning technique that provides the precision required for realising electrical contacts for solar cells and does not involve a masking step.

### SUMMARY OF THE INVENTION

In accordance with a first aspect the present invention provides a method for forming a contact of a photovoltaic device, the method comprising the steps of:
depositing a polymeric layer onto a surface of the photovoltaic device;
exposing a region of the polymeric layer to laser light;
developing the polymeric layer to create at least one opening in the polymeric layer for accessing a respective portion of the surface;
depositing a conductive material into the at least one opening of the polymeric layer in a manner such that the conductive material is in electrical contact with the respective portion of the surface; and
removing at least a portion of the remaining developed polymeric layer from the surface.

In an embodiment the polymeric layer partially melts under the influence of the laser light. Some of the physical properties of the melted portion change so that the melted portion can be removed in the developing solution. Alternatively, the polymeric layer can be initially dissolvable in the developing solution, and the melted portion can become resistant to the developer.

Advantageously, the polymeric layer may comprise a photoresist material, so that the layer can be developed using commercial developing solutions.

In an embodiment, the step of depositing the polymeric layer comprises spraying a sprayable polymeric material onto the surface. The polymeric material may be a positive photoresist material and the at least one portion of the surface may be located below the exposed region of the photoresist material. The polymeric layer may comprise KONTACT CHEMIE POSITIV 20 photoresist or ELECTROLUBE PRP positive photoresist.

In an embodiment, the step of depositing the polymeric layer comprises spinning a spinnable polymeric material onto the surface or applying a dry film polymeric material onto the surface. This step may be repeated multiple times.

In an embodiment, the method further comprises the step of thermally treating the polymeric layer after depositing the polymeric layer. Thermally treating the polymeric layer may comprise baking the polymeric layer at a temperature between 20° C. and 100° C. for example for a period of time between 5 minutes and 60 minutes.

Depositing the polymeric layer may comprise depositing a stack of multiple polymeric layers and performing respective thermal treatments for each deposited polymeric layer.

In an embodiment, thermally treating the polymeric layer comprises baking the photoresist using a belt furnace or a hot dry gas. In alternative embodiments the photoresist may be baked using a hot plate.

In an embodiment, the step of exposing a region of the polymeric layer to a laser light comprises moving the laser light across the region to progressively expose the region to the laser light.

Alternatively, the photovoltaic device may be positioned on a movable stage, such as a movable belt, and the step of exposing a region of the polymeric layer to the laser light may comprise moving the movable belt in relation to the laser light.

The laser light may comprise a plurality of laser beams. The plurality of laser beams may be created by a plurality of laser sources. Splitting one or more laser beams using one or more beam splitters may also create the plurality of laser beams.

In an embodiment, the laser light reaches a portion of the surface through the polymeric layer and affects properties of the portion of the surface. The portion of the surface may partially melt under the influence of the laser light.

In embodiments, the laser light has a wavelength in the blue wavelength and/or a ultra-violet wavelength range. The laser light may have a wavelength between 400 nm and 410 nm.

The optical power of the laser light that reaches the region of the polymeric layer may be between 0.1 mW and 1 W.

In an embodiment, the step of developing the polymeric layer comprises exposing the polymeric layer to a chemical solution comprising 0.4% to 2.0% NaOH. The polymeric layer may be exposed to the chemical solution for a time period between 30 seconds and 10 minutes.

In an embodiment, the method further comprises the step of exposing the portion of the surface to a chemical solution containing hydrofluoric acid. In an embodiment, the method further comprises the step of plasma etching the portion of the surface.

In embodiments, the step of depositing a first conductive material into the openings of the polymeric layer comprises depositing the first conductive material onto the portion of the surface by electrochemical plating or electroless plating. The first conductive material may comprise copper or nickel.

In embodiments, the method further comprises depositing a conductive layer to the portion of the surface prior to depositing the first conductive material to promote adhesion of the first conducting material to the portion of the surface.

In other embodiments, the method further comprises chemically treating the portion of the surface prior to depositing the first conductive material to promote adhesion of the first conducting material to the portion of the surface.

In an embodiment, the method further comprises depositing a second conductive material to the surface of the photovoltaic device before or after removing the polymeric layer from the surface, in a manner such that the second conductive material at least partially surrounds the first conductive material. The step of depositing a second conductive material may comprise electrochemical plating of tin or electroless plating of tin.

In an embodiment, the step of removing the polymeric layer from the surface comprises exposing the polymeric layer to a chemical solution comprising Acetone, 1-Methyl-2-pyrrolidone, turpentine or NaOH.

In accordance with a second aspect, the present invention provides a method for forming a photovoltaic device, the method comprising the steps of:
providing an extrinsic silicon substrate;
depositing an intrinsic silicon layer onto a surface of the silicon substrate;
depositing an extrinsic silicon layer on at least a portion of the intrinsic silicon layer;
depositing a layer of transparent conductive oxide onto at least a portion of the deposited extrinsic silicon layer; and
forming a patterned metallic electrical contact onto the layer of transparent conductive oxide using a method in accordance with the first aspect.

In accordance with a third aspect, the present invention provides a photovoltaic device comprising:
an extrinsic silicon substrate;
an intrinsic silicon layer in contact with at least a portion of a surface of the silicon substrate;
an extrinsic silicon layer in contact with at least a portion of the intrinsic silicon layer;
a transparent conductive oxide layer in contact with at least a portion of the extrinsic silicon layer; and
a patterned metallic contact in electrical contact with the layer of transparent conductive oxide formed in accordance with the first aspect of the present invention.

In accordance with a fourth aspect, the present invention provides a photovoltaic device comprising:
an extrinsic silicon substrate;
a thin oxide layer in contact with at least a portion of a surface of the silicon substrate whereby the thin oxide in itself is a tunneling contact;
an extrinsic silicon layer in contact with at least a portion of the thin oxide layer;
a transparent conductive oxide layer in contact with at least a portion of the extrinsic silicon layer; and
a patterned metallic contact in electrical contact with the layer of transparent conductive oxide formed in accordance with the first aspect.

Advantageous embodiments of the present invention provide a method for forming a contact of a photovoltaic device and which allows creating a patterned metallic contact to a surface of the photovoltaic device avoiding a screen-printing step. These embodiments provide some of the benefits usually provided by conventional lithography techniques, but without having to use photolithographic masks. These embodiments use laser light to expose a photoresist layer applied to a surface of the photovoltaic device. The laser light is used in conjunction with a sprayable photoresist, which is generally less expensive than conventional photoresists traditionally used in lithography processes. This makes the method of these embodiments more suitable for high volume production of photovoltaic devices.

An advantage of embodiments of the method is that the pattern resolution achieved is related to the size of a portion of the photoresist material that melts under exposure and not the conventional ‘resolution rating’ of the photoresist used. This allows obtaining higher resolutions using cheaper lower resolution photoresists. For example a resolution of 40 μm to 50 μm may be obtained using a photoresist with 200 μm resolution.

### BRIEF DESCRIPTION OF THE DRAWINGS

Features and advantages of the present invention will become apparent from the following description of embodiments thereof, by way of example only, with reference to the accompanying drawings in which:

FIGS. 1 to 7 are schematic illustrations of a photovoltaic device at different stages of a contact formation process in accordance with embodiments of the invention;

FIG. 8 is a flow-diagram outlining processing steps for forming a contact to a photovoltaic device in accordance with embodiments of the invention; and

FIG. 9 is a schematic illustration of an apparatus used to implement some of the steps of FIG. 8.

### DETAILED DESCRIPTION OF SPECIFIC EMBODIMENTS

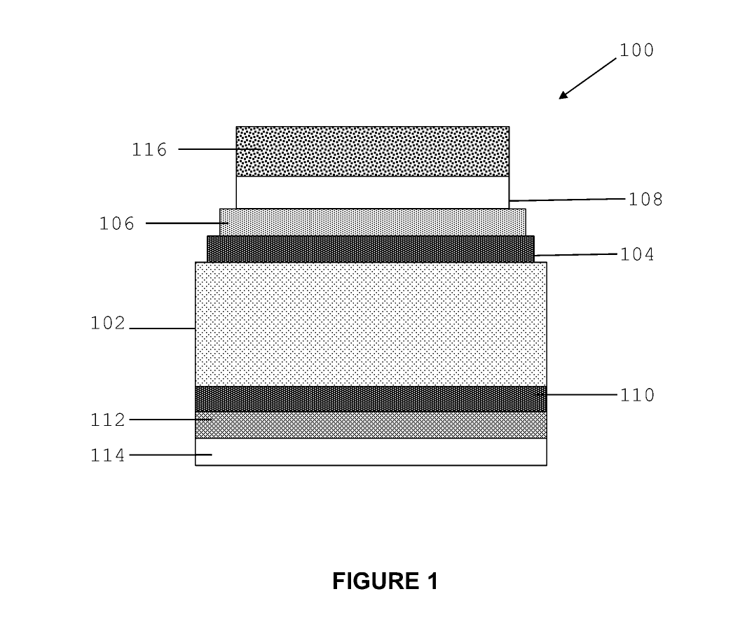

Referring now to FIG. 1, there illustrated processing steps of a photovoltaic device 100. The photovoltaic device 100 of FIG. 1 has at this stage neither a front contact nor a back contact.

The device 100 comprises an n-doped silicon substrate 102, an intrinsic silicon layer 104 disposed onto a surface of the silicon substrate 102 and a p-type silicon layer 106 disposed onto a portion of the intrinsic silicon layer 104. Further, the device 100 has a layer of transparent conductive oxide 108 disposed onto a portion of the p-type silicon layer 106.

The device 100 can potentially be a bifacial photovoltaic device and the structure of the topside of the device 100 is repeated at the bottom side of device 100. At the bottom side, the device has an intrinsic silicon layer 110, an n-type silicon layer 112 and a layer of transparent conductive oxide 114.

The method for forming a contact of a photovoltaic device described herein may be used for example to form a contact of device 100 at a surface portion of the front transparent conductive oxide 108 or the back transparent conductive oxide 114.

In accordance with embodiments, depositing a polymeric layer onto a surface portion of the transparent conductive oxide 108, for example, can form a contact at a surface portion of the front transparent conductive oxide layer 108. A region of the polymeric layer is then exposed to laser light. By selecting the exposed region, the contact can be formed in accordance with a pattern. For example, the contact can be formed as a pattern comprising a plurality of fingers designed to optimise the extraction of charge carriers from the device 100 while minimising the shading losses at the front surface. Depending on whether a positive or negative photoresist is used, the regions at which the contacts will be formed may be exposed or alternatively adjacent regions may be exposed.

The laser light melts portions of the polymeric layer and changes some of the physical properties of the layer at these portions. For example the melted portion can become dissolvable in a developing solution, or resistant to a developing solution. By developing the polymeric layer, a pattern of openings can be created in the layer corresponding to the exposed portions of the layers, or to the negative of the exposed portions.

In the embodiment described herein the polymeric layer comprises a layer of positive photoresist, so the exposed portions of the layer can be developed using commercial developing solutions and techniques. The openings are created at the locations where the metallic fingers will be positioned.

The conductive material forming the contact is then deposited into the openings of the photoresist layer so that the conductive material is in electrical contact with the portion of the surface. The remaining portion of the photoresist layer is then removed from the surface to just leave the patterned contact.

A sprayable photoresist layer 116 disposed at a surface portion of the front transparent conductive oxide layer 108 is shown in FIG. 1. In the illustrated embodiment the photoresist layer 116 has been deposited using a spray-on deposition technique. In contrast with conventional photoresist deposition methods, the spray on deposition enables depositing a uniform layer of photoresist quickly with a level of uniformity sufficient for solar cell applications. Further, the spray on deposition improves the efficiency in using photoresist as it minimises waste of photoresist. The sprayable photoresist layer 116 is in this example ELECTROLUBE PRP, which is a positive photoresist material. This is a commercially available photoresist material. The cost of photoresist is one of the factors that make use of traditional photolithography techniques in the mass production of photovoltaic devices unfavourable. Traditionally photolithography has never been adopted in high volume production lines. However, the inventor has found that the use of spray on materials, such as ELECTROLUBE PRP positive photoresist material, mitigates some of the drawbacks commonly associated with use of photoresist in the photovoltaic industry.

Depending on the morphology of the surface of the transparent conductive oxide 108, one or more spray on steps of ELECTROLUBE PRP positive photoresist material may be required. A lower number of steps are generally required for a flatter surface. Textured surfaces generally require more spray on steps.

After the spray on deposition, the photoresist layer is thermally treated to let solvents evaporate. In the embodiment described device 100 is baked in a baking oven at circa 50° C. for about 20 minutes. Temperature and duration of the baking process may vary. For example, in a production environment the device 100 may be disposed onto the belt of a belt furnace and be heated for longer time periods at a lower temperature or heated using a hot dry gas.

After the photoresist layer 116 has been baked, a region of the photoresist layer 116 is exposed to a laser light to locally change chemical properties of the photoresist material.

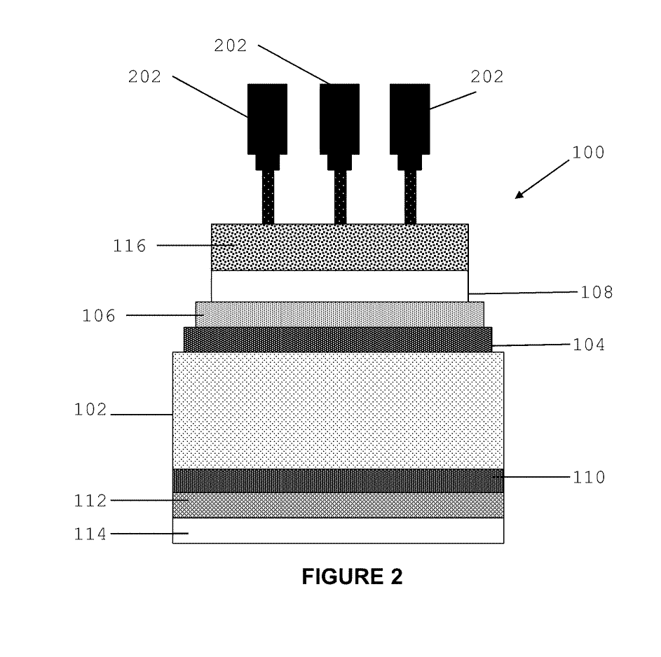

Referring to FIG. 2, there are shown three separate laser sources 202 used to expose a region of the photoresist layer 116. Alternatively, a single and more powerful laser sources may be used and a generated laser beam may be split using suitable beam splitters. The laser light is focused onto the photoresist layer 116 using suitable optical components.

The laser sources 202 may be moved relative to the device 100 to expose the region to the laser light. In additionally or alternatively, the device 100 may be mounted to a movable stage, such as a movable belt, and may be moved relative to the laser light.

In a production environment, a plurality of devices would likely be slowly moving on a belt and a plurality of laser sources would be positioned in proximity of the devices, and possibly move relative to the devices, to expose regions of photoresist to the laser light.

In some cases the laser light may reach a portion of the surface of transparent conductive oxide 108 through the photoresist layer and affect its physical properties, for example its conductivity.

During the exposure process, the photoresist layer 116 partially melts under the influence of the laser light. In the embodiment described, the pattern resolution is related to the size of the melted portion of the photoresist layer. This allows obtaining higher resolutions using cheaper lower resolution photoresists providing a cost advantage. For example, a resolution of 40 μm to 50 μm may be obtained using a photoresist with 200 μm resolution.

In the embodiment described, the laser light of laser sources 202 used to expose the ELECTROLUBE PRP positive photoresist material have a wavelength of 405 nm and an optical power of 1 mW. Different wavelengths and optical powers may be used in alternative embodiments, depending on exposure time and other processing parameters.

Using a laser light to expose a positive photoresist is a maskless process which is in contrast to traditional means of photolithography that require expensive photomasks and mask aligners. The ability to directly expose the photoresist by simply scanning the laser light across the photoresist can result in high throughput suitable for mass production of photovoltaic devices.

As the laser light is focused to a spot size in the order of a few microns to tens of microns the intensity of the laser light incident on the photoresist is sufficiently high that the exposure period can be short. Therefore, a fast laser speed suitable for manufacturing can be used. Also, as the laser light is focused, the optical output of the laser can be in the range of 0.1 mW to hundreds of mW, eliminating the need to use large expensive lasers with complex cooling systems. Therefore, a manufacturing tool to perform the laser exposure process could be relatively inexpensive and simple, as required for high volume commercial production. In comparison, the commercial laser tools used to fabricate laser doped selective emitter photovoltaic structures have an optical power output in the order of tens of Watts and require complex cooling systems which make them relatively expensive.

The photoresist material is a consumable material in the fabrication process. Thus in order to commercialise a photovoltaic process which involves a photoresist material, the cost of the photoresist material must be contained, the photoresist has to be suitable to be applied and removed quickly and easily with little material wastage and good production yields. The Electrolube PRP and Kontakt Chemie Positiv 20 spray on positive photoresists meet these criteria. In contrast, traditional photoresists are spun on resulting in high wastage due to much of the photoresist spinning off the surface. Traditional photoresists are also more expensive, require large amounts to completely cover a large surface and can result in poor yields due to a high number of wafer breakages.

Combining the low cost spray on positive photoresist with direct exposure using a low powered fasting moving laser light provides an alternative commercial solution to traditional photovoltaic photolithography techniques.

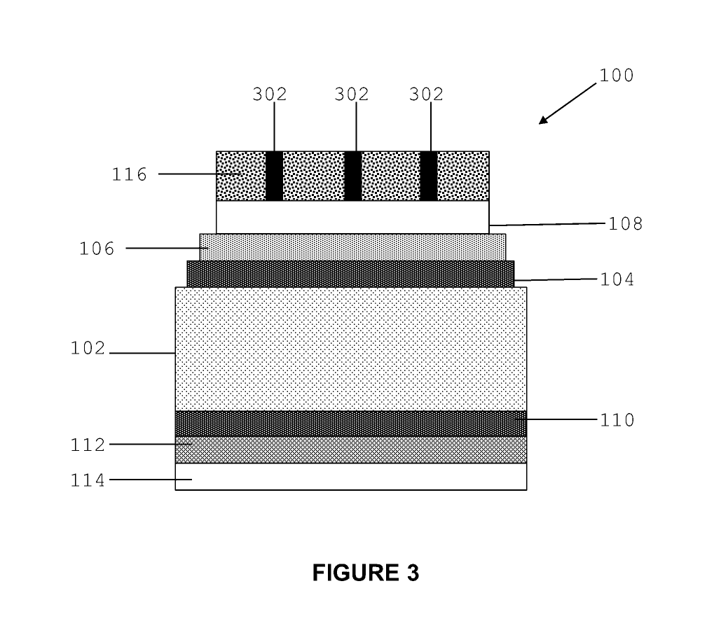

FIG. 3 shows regions 302 of the photoresist layer 116 that have been exposed to laser beams 202. The chemical composition of photoresist layer 116 at regions 302 has been changed by the laser light and the exposed ELECTROLUBE PRP positive photoresist material at regions 302 can be developed using a chemical solution comprising 0.7% NaOH by weight. The exposure of the photoresist layer 116 to the development solution is performed for about 5 minutes.

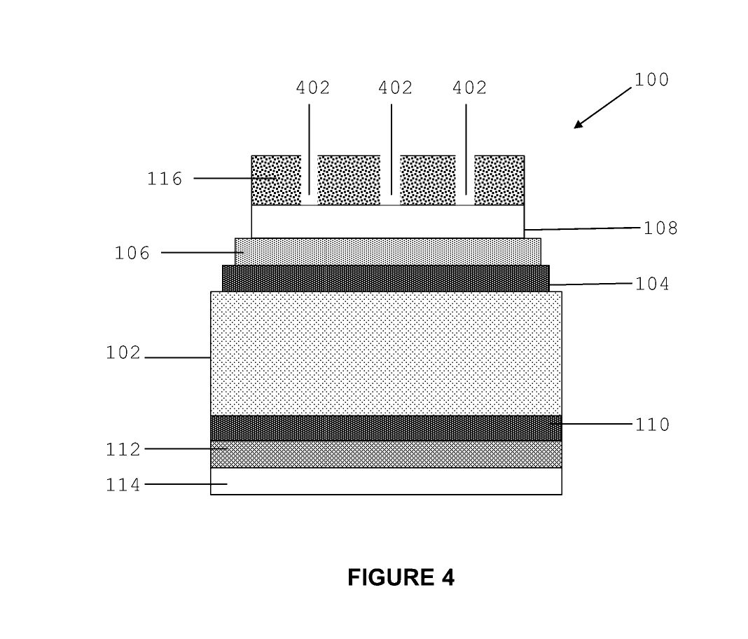

The result of the development process is shown in FIG. 4, which illustrates openings 402 in the photoresist layer 116. To create the electrical contact a conductive material can be deposited into openings 402.

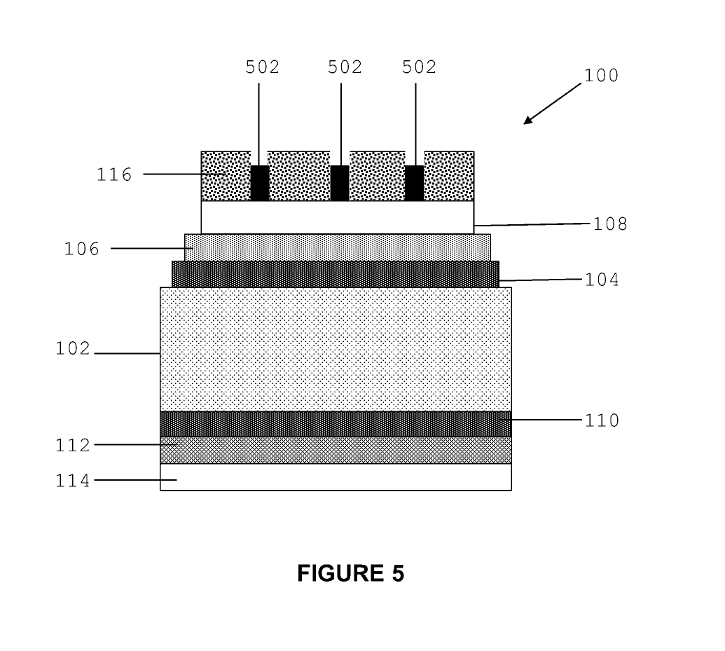

Referring now to FIG. 5, there is shown a first conductive material in the openings 402 of the photoresist layer 116. The first conductive material is provided in the form of copper fingers 502. The copper fingers 502 are deposited by electrochemical plating methods. This can be achieved for example by forward biasing the solar cell. By forward biasing the photovoltaic device electrons will be driven through the device to the transparent conductive oxide on the p-type side 108 and therefore are able to react with the metallic ions in the plating solution to form plated metallic contacts.

FIGS. 1 to 7 illustrate a method for forming a patterned metallic contact to the p-type side of the photovoltaic device; however the method can also be applied to the n-type side of the photovoltaic device. In the case of applying the method to the n-type side of the photovoltaic device, the deposition of the copper fingers can also be performed through the photoresist openings by means of electrochemical plating. This can be achieved for example by light-induced plating or bias assisted light-induced plating.

Alternatively, electroless plating can deposit the copper fingers 502. Other materials, such as nickel, tin or silver can also be deposited into openings 402 using plating methods.

In the embodiment described, a further step of depositing a layer onto the portion of transparent conductive oxide 108 prior to plating the copper fingers 502 is performed to promote adhesion of copper to the transparent conductive oxide 108. Furthermore, a chemical treatment of the portion of transparent conductive oxide 108 can be performed to promote adhesion. In some cases the chemical treatment and the additional layer can be used together with the final aim of improving the adhesion of copper.

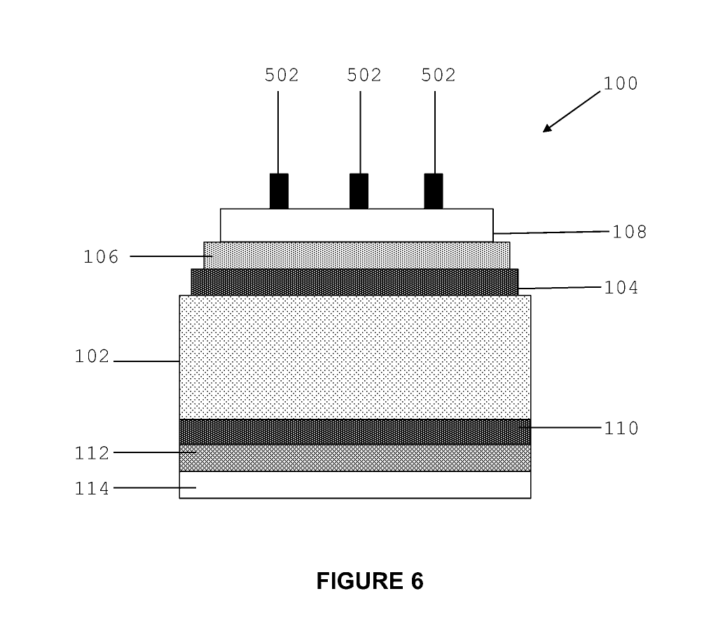

Referring now to FIG. 6, there is shown the device 100 after the photoresist layer 116 has been removed. The photoresist layer 116 is removed by exposing the photoresist layer 116 to a chemical solution comprising Acetone, 1-Methyl-2-Pyrrolidone, turpentine or NaOH. Alternatively the entire remaining portions of the photoresist layer 116 may be exposed to the laser light or another source of light and removed in a manner similar to the development step.

In the embodiment described, a further step is performed to deposit a second conductive material. The second conductive material at least partially surrounds the copper fingers 502. This step may be performed before or after the removal of photoresist layer 116.

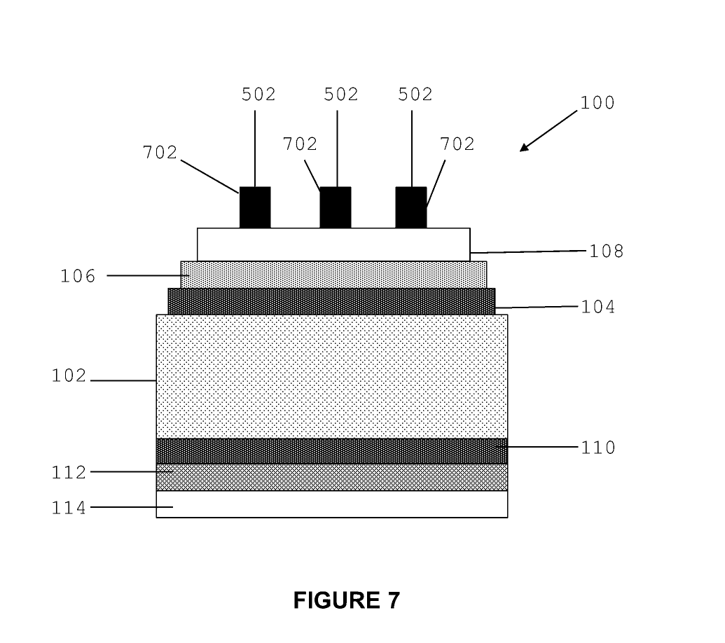

Referring now to FIG. 7, there is shown device 100 in which the second conductive material has been deposited after the removal of the photoresist layer 116. In FIG. 7 the second conductive material is a tin layer 702 deposited by exposing a portion of device 100 to an electroless tin solution. Alternatively, the tin layer 702 may be deposited by electrochemical plating.

FIGS. 1 to 7 show the device 100 during processing steps to form a front contact to the p-type side of a front junction photovoltaic device in accordance with embodiments of the present invention. The device 100 is configured as a Heterojunction Intrinsic Thin Layer (HIT) cell, which can potentially be a bifacial photovoltaic device. Similar method steps may be used for example to form a contact at the bottom surface of the device 100 or a contact to the front and/or backside of a Metal Oxide Semiconductor (MOS) or Metal Insulated Semiconductor (MIS) solar cell. It is also possible to fabricate a photovoltaic device with a contact formed in accordance with embodiments of the present invention on either the p-type or n-type side of the photovoltaic device and the other side having a contact formed by traditional means, for example screen printing, sputtering or evaporation.

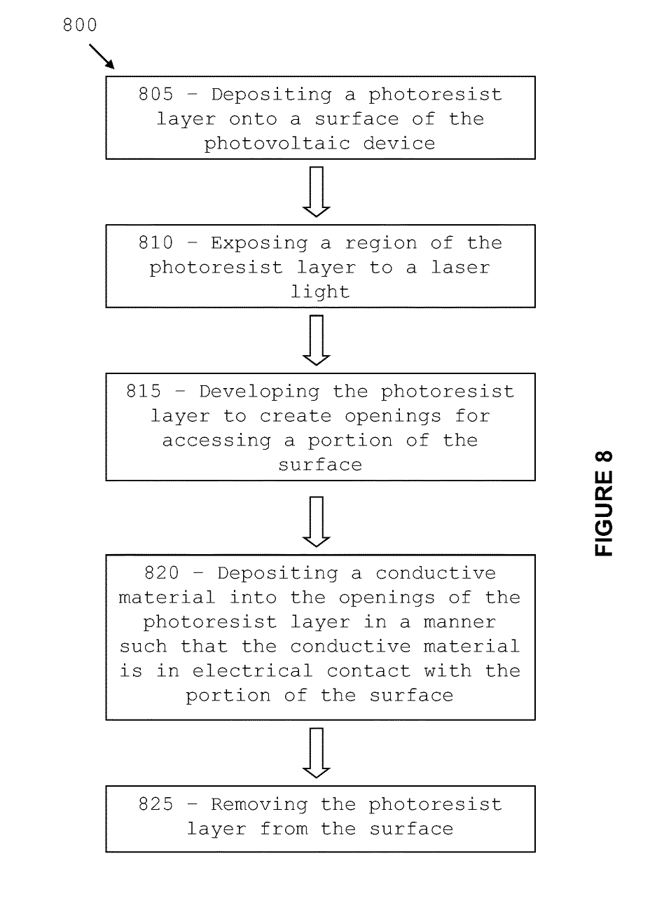

FIG. 8 is a flow-diagram 800 with processing steps used to form a contacting structure in according with embodiments. At step 805 a photoresist layer is deposited onto a surface of the photovoltaic device. At step 810, a region of the photoresist layer is exposed to laser light and, at step 815, the photoresist layer is developed to create openings for accessing a portion of the surface.

Art step 820 a conductive material is deposited into the openings of the photoresist layer in a manner such that the conductive material is in electrical contact with the portion of the surface. At step 825, the photoresist layer is removed from the surface.

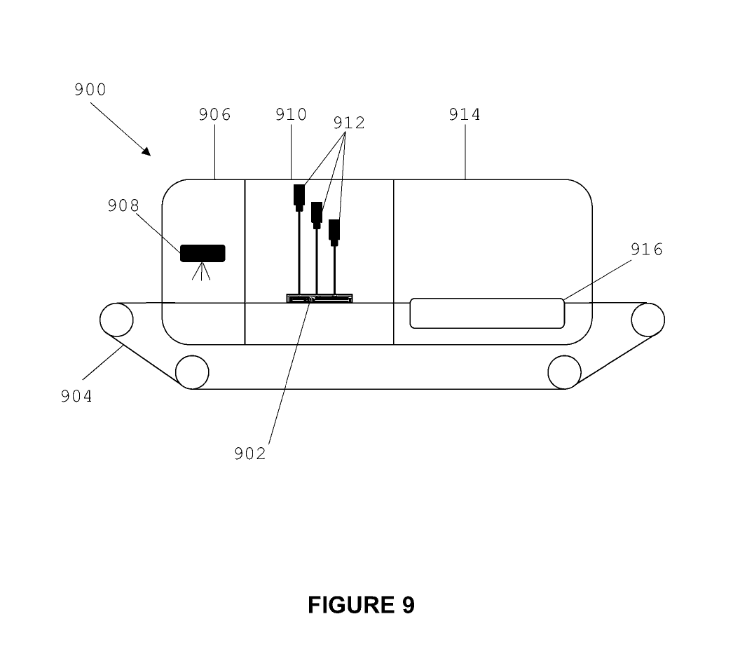

Referring now to 9, there is shown a schematic illustration of an apparatus 900 used to implement some of the steps of method 800. Solar cell 902 is transported on a belt 904 through a number of stages of the apparatus 900. Apparatus 900 may represent a portion of a larger solar cell production line. In zone 906, ELECTROLUBE PRP positive photoresist is deposited on the solar cell 902 using spraying assembly 908. The solar cell 902 is then transported to zone 910 where it is exposed to laser light. In this form of apparatus, an array of stationary lasers 912 is positioned over the solar cell 902. As the solar cell 902 moves under the lasers in one direction, straight lines of photoresist are exposed to laser light to create the finger pattern. The solar cell 902 is then moved to the developing zone 914 where a developer bath 916 is used for development. After development, solar cell 902 is moved to a deposition stage (not shown in FIG. 9) to deposit the metallic material which forms the fingers and other stages to complete the manufacturing process.

Embodiments of the present invention may also be used to form a contact for a different type of solar cell. Some variations of the method steps may be required depending on the solar cell. These variations do not depart from the main spirit of the invention, which enables masking a surface of the device using a laser and a polymeric layer.

In some alternative embodiments, the polymeric layer may be applied to the surface using a dry film technique and/or may be baked using a hot plate. Further, additional steps may be performed to access the front or the back conductive surface of the photovoltaic device. For example, once openings in the polymeric layer have been formed, the surface of the device may be exposed to a chemical solution containing hydrofluoric acid to remove dielectric portions. Alternatively, these portions may be removed using a plasma-etching step.

The term “comprising” (and its grammatical variations) as used herein are used in the inclusive sense of “having” or “including” and not in the sense of “consisting only of”.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1-36. (canceled)

37. A method for forming a contact for a photovoltaic device, the method comprising the steps of:
depositing a polymeric layer onto a surface of the photovoltaic device;
exposing a region of the polymeric layer to laser light;
developing the polymeric layer to create at least one opening in the polymeric layer for accessing a respective portion of the surface;
depositing a conductive material into the at least one opening of the polymeric layer in a manner such that the conductive material is in electrical contact with the respective portion of the surface; and
removing at least a portion of the remaining developed polymeric layer from the surface.

38. The method of claim 37 wherein the polymeric layer partially melts under the influence of the laser light.

39. The method of claim 38 wherein the laser light reaches a portion of the surface through the polymeric layer and affects properties of the portion of the surface.

40. The method of claim 39 wherein the portion of the surface partially melts under the influence of the laser light.

41. The method of claim 37 wherein the polymeric layer comprises a positive photoresist material and wherein the at least one portion of the surface is located below the exposed region of the polymeric layer.

42. The method of claim 37 wherein the method further comprises thermally treating the polymeric layer at a temperature between 40° C. and 60° C.

43. The method of claim 42 wherein thermally treating the polymeric layer comprises baking the polymeric layer for a period of time between 15 minutes and 45 minutes.

44. The method of claim 37 wherein depositing the polymeric layer comprises depositing a stack of multiple polymeric layers and performing respective thermal treatments for each deposited polymeric layer.

45. The method of claim 37 wherein the laser light has a wavelength between 400 nm and 410 nm.

46. The of claim 37 wherein the optical power of the laser light that reaches the region of the polymeric layer is between 0.1 mW and 1 W.

47. The method of claim 37 wherein developing the polymeric layer comprises exposing the polymeric layer to a chemical solution comprising 0.4% to 2.0% NaOH by weight.

48. The method of claim 47 wherein the polymeric layer is exposed to the chemical solution for a time period between 30 seconds and 10 minutes.

49. The method of claim 37 wherein the method further comprises exposing the portion of the surface to a chemical solution containing hydrofluoric acid.

50. The method of claim 37 wherein the method further comprises plasma etching the portion of the surface.

51. The method of claim 37 wherein the step of depositing a conductive material into at least one opening of the polymeric layer comprises electrochemical plating or electroless plating a first conductive material to the portion of the surface.

52. The method of claim 51 wherein the method further comprises the step of depositing a layer to the portion of the surface prior to depositing the first conductive material or chemically treating the portion of the surface prior to depositing the first conductive material to promote adhesion of the first conductive material to the portion of the surface.

53. The method of claim 51 wherein the method further comprises the step of depositing a second conductive material onto the surface of the photovoltaic device before or after the step of removing the polymeric layer from the surface, in a manner such that the second conductive material at least partially surrounds the first conductive material.

54. A method for forming a photovoltaic device, the method comprising the steps of:
providing an extrinsic silicon substrate;
depositing an intrinsic silicon layer onto a surface of the silicon substrate;
depositing an extrinsic silicon layer on at least a portion of the intrinsic silicon layer;
depositing a layer of transparent conductive oxide onto at least a portion of the extrinsic silicon layer; and
forming a patterned metallic electrical contact onto the layer of transparent conductive oxide using a method in accordance with claim 37.

55. A photovoltaic device comprising:
an extrinsic silicon substrate;
an intrinsic silicon layer in contact with at least a portion of a surface of the silicon substrate;
an extrinsic silicon layer in contact with at least a portion of the intrinsic silicon layer;
a transparent conductive oxide layer in contact with at least a portion of the extrinsic silicon layer; and
a patterned metallic contact in electrical contact with the layer of transparent conductive oxide formed in accordance with claim 37.

56. A photovoltaic device comprising:
an extrinsic silicon substrate;
a thin oxide layer in contact with at least a portion of a surface of the silicon substrate whereby the thin oxide in itself is a tunneling contact;
an extrinsic silicon layer in contact with at least a portion of the thin oxide layer;
a transparent conductive oxide layer in contact with at least a portion of the extrinsic silicon layer; and
a patterned metallic contact in electrical contact with the layer of transparent conductive oxide formed in accordance with claim 37.
